(19) United States
(12) Patent Application Publication
(10) Pub. No.: US 2010/0303159 A1
(43) Pub. Date: Dec. 2, 2010

(54) APPARATUS AND METHOD FOR SYNCHRONIZING USER OBSERVABLE SIGNALS

(76) Inventors: Mark Alan Schultz, Carmel, IN (US); Ronald Douglas Johnson, Westfield, IN (US); Robert Andrew Rhodes, Carmel, IN (US)

Correspondence Address: Robert D. Shedd, Patent Operations;THOMSON Licensing LLC, P.O. Box 5312, Princeton, NJ, 08543-5312, US

(21) Appl. No.: 12/733,768

(22) PCT Filed: Jul. 31, 2008
(86) PCT No.: PCT/US2008/009240

§ 371 Date: Mar. 18, 2010

Related U.S. Application Data
(60) Provisional application No. 60/994,805, filed on Sep. 21, 2007.

(51) Int. Cl. H03L 7/00; H04N 7/26; H04L 27/00

(52) U.S. Cl. 375/240.28; 375/295; 327/161; 375/E07.026

(57) ABSTRACT

An apparatus and method provides synchronization between user observable signals including audio and/or video signals. According to an exemplary embodiment, the apparatus includes an input point for receiving an encoded signal. A circuit time-shifts the encoded signal to generate a time-shifted encoded signal. A first decoder decodes the time-shifted encoded signal to generate a first decoded signal and provides the first decoded signal for a first system. The first system converts the first decoded signal to a first user observable signal. The input point also provides the encoded signal for a second system including a second decoder, an encoder, and a third decoder coupled in series which enables generation of a second user observable signal. The time-shifting performed by the circuit is adjustable and enables the first user observable signal to become substantially synchronized with the second user observable signal.

This application claims the benefit of U.S. Provisional Application No. 60/994,805, filed Sep. 21, 2007.

The present invention generally relates to an apparatus and method for providing synchronization between user observable signals including audio and/or video signals. An apparatus such as a set-top box (STB) processes audio and/or video signals for providing information to a user. For example, the STB may process such signals to enable reproduction of the audio and/or video components of a program on a main television (TV) that is in the vicinity of, or local to, the STB. The STB may also use an audio/video encoder (e.g., plugged into the STB or included as an integral component thereof) to generate a signal suitable for transmission (e.g., via a wireless or wired is communication medium) as a secondary stream to a second apparatus, such as a portable TV that is in a location remote from the STB.

In the aforementioned configuration, when both the main TV that is local to the STB and the portable TV that is remote from the STB are both tuned to the same station, the encoder and transmission of the secondary stream introduces a delay on the order of 0.5 to 1.5 seconds between reproduction of the program material on the main TV, and reproduction on the portable TV. At the portable TV, the delay is the same for both audio and video content. That is, the encoder used by the STB introduces the same delay for both audio and video content. However, if the portable TV is in a location at which the audio from the main TV can be heard (e.g., the main TV is in one room of a home and the portable TV is in an adjacent room), and both the main and portable TVs are reproducing the same program content, then a user of the portable TV may hear the same audio program from two sources that have 0.5 to 1.5 second delays between them. This may be particularly annoying to the user.

Accordingly, there is a need for an apparatus and method for addressing the aforementioned problem by providing synchronization between audio and/or video signals in such situations. The present invention addresses these and/or other issues.

In accordance with an aspect of the present invention, an apparatus is disclosed. According to an exemplary embodiment, the apparatus comprises an input point for receiving an encoded signal. A circuit time-shifts the encoded signal to generate a time-shifted encoded signal. A first decoder decodes the time-shifted encoded signal to generate a first decoded signal and provides the first decoded signal for a first system. The first system converts the first decoded signal to a first user observable signal. The input point also provides the encoded signal for a second system including a to second decoder, an encoder, and a third decoder coupled in series which enables generation of a second user observable signal. The time-shifting performed by the circuit is adjustable and enables the first user observable signal to become substantially synchronized with the second user observable signal.

In accordance with another aspect of the present invention, a method is disclosed. According to an exemplary embodiment, the method comprises the steps of receiving an encoded signal; time-shifting the encoded signal to generate a time-shifted encoded signal; decoding the time-shifted encoded signal via a first decoder to generate a first decoded signal; providing the first decoded signal for a first system; converting the first decoded signal to a first user observable signal via the first system; providing the encoded signal for a second system including a second decoder, an encoder, and a third decoder coupled in series; generating a second user observable signal via the second system; and wherein the time-shifting step is adjustable and enables the first user observable signal to become substantially synchronized with the second user observable signal.

The above-mentioned and other features and advantages of this invention, and the manner of attaining them, will become more apparent and the invention will be better understood by reference to the following description of embodiments of the invention taken in conjunction with the accompanying drawings, wherein:

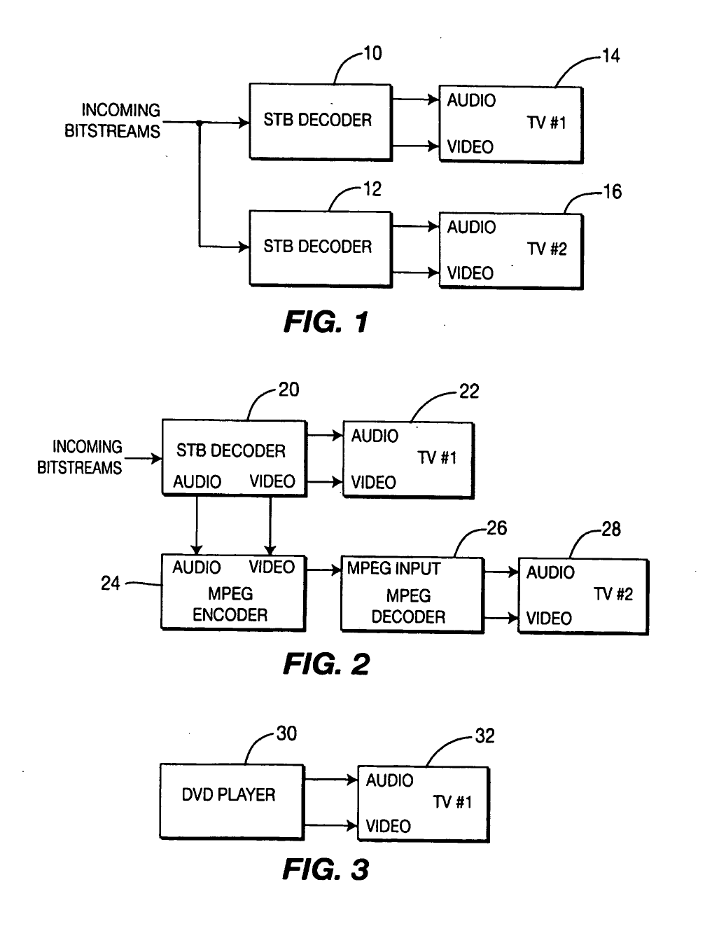

FIG. 1 shows an exemplary configuration in which audio and video delays are approximately equal;

FIG. 2 shows an exemplary configuration in which audio and video delays are unequal;

FIG. 3 shows another exemplary configuration in which audio and video delays are approximately equal;

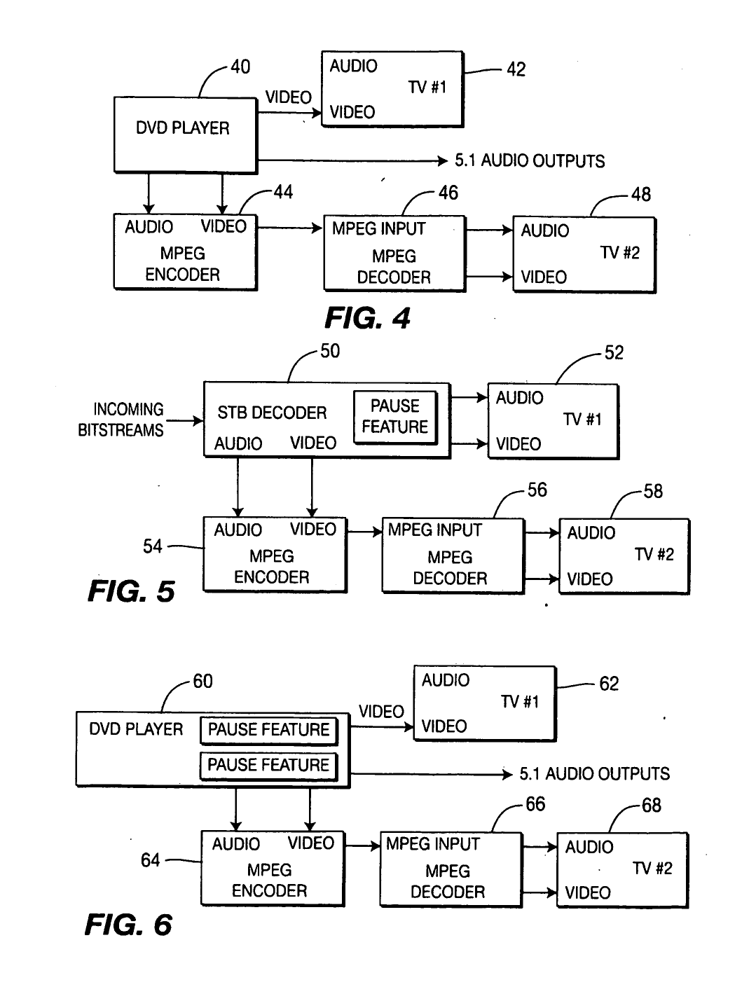

FIG. 4 shows another exemplary configuration in which audio and video delays are unequal;

FIG. 5 shows an exemplary configuration that includes a pause feature according to an embodiment of the present invention;

FIG. 6 shows another exemplary configuration that includes a pause feature according to an embodiment of the present invention;

FIG. 7 shows an example of how the present invention may be implemented;

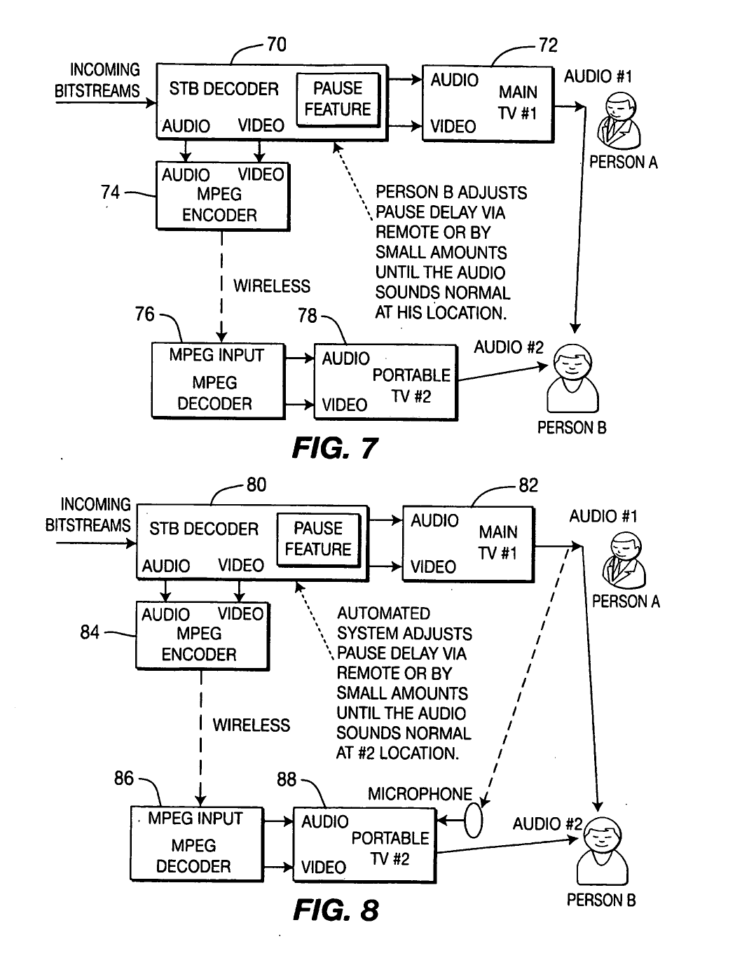

FIG. 8 shows another example of how the present invention may be implemented;

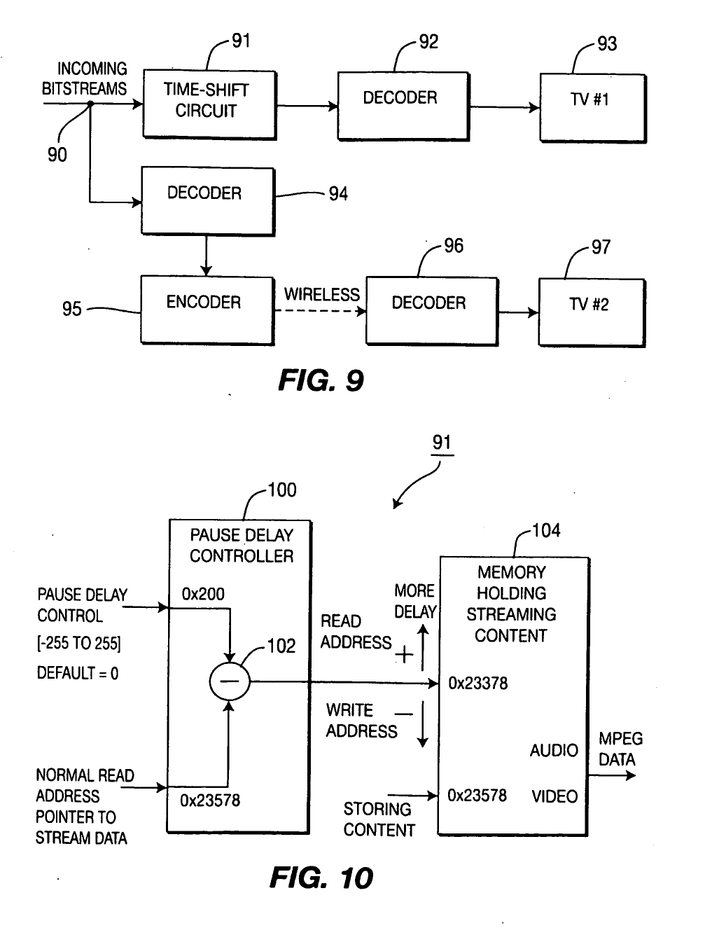

FIG. 9 shows a block diagram including further exemplary details of how the pause feature of the present invention may be implemented; and

FIG. 10 shows further exemplary details of the time-shift circuit of FIG. 9.

The exemplifications set out herein illustrate preferred embodiments of the invention, and such exemplifications are not to be construed as limiting the scope of the invention in any manner.

Referring now to the drawings, and more particularly to FIG. 1, an exemplary configuration in which audio and video delays are approximately equal is shown. In particular, the exemplary configuration of FIG. 1 includes STB decoders 10 and 12 that decode incoming bitstreams and provide corresponding audio and video signals to TV#1 14 and TV#2 16, respectively, in which the audio and video delay introduced by STB decoder 10 and TV#1 14 is approximately equal to the audio and video delay introduced by STB decoder 12 and TV#2 16.

FIG. 2 shows an exemplary configuration in which audio and video delays are unequal. In particular, the exemplary configuration of FIG. 2 includes a STB decoder 20 that decodes incoming bitstreams and provides corresponding audio and video signals to TV#1 22, and also provides corresponding audio and video signals to an MPEG encoder 24. MPEG encoder 24 encodes the audio and video signals received from STB decoder 20 and provides an encoded signal to an MPEG decoder 26 which decodes the encoded signal and provides corresponding audio and video signals to TV#2 28. In FIG. 2, the addition of encoding and decoding functions in the signal path to TV#2 28 introduces a delay that renders the audio and video delays between the outputs provided by TV#1 22 and TV#2 28 unequal. Accordingly, with the exemplary configuration of FIG. 2, if TV#1 22 and TV#2 28 are within relatively close proximity of each other (e.g., in adjacent rooms, etc.), the audio will be annoying due to the time delay of the different decoders 20 and 26.

Referring to FIG. 3, another exemplary configuration in which audio and video delays are approximately equal is shown. In particular, the exemplary configuration of FIG. 3 includes a digital versatile disc (DVD) player 30 that provides audio and video signals to TV#1 32. In FIG. 3, the audio and video delays are designed to be approximately equal. FIG. 4 shows another exemplary configuration in which audio and video delays are unequal. In the exemplary configuration of FIG. 4, which incorporates a DVD player 40, the audio and video delays are not equal in TV#1 42 because DVD player 40 has no information regarding the delay through TV#1 42. The delays in TV#2 48 and DVD player 40 are also not matched since the audio processing function of DVD player 40 has no information regarding the delays introduced by MPEG encoder 44 and MPEG decoder 46. In FIG. 4, if TV#2 48 is a portable unit, multiple delays will be found in both the audio and video outputs.

FIG. 5 shows an exemplary configuration that includes a pause feature according to an embodiment of the present invention. In particular, the exemplary configuration of FIG. 5 includes a STB decoder 50 having a pause feature, which will be described later herein. STB decoder 50 decodes incoming bitstreams and provides corresponding audio and video signals to TV#1 52, and also provides corresponding audio and video signals to MPEG encoder 54. MPEG encoder 54 encodes the audio and video signals received from STB decoder 50 and provides an encoded signal to an MPEG decoder 56 which decodes the encoded signal and provides corresponding audio and video signals to TV#2 58.

One of the main problems present in the exemplary configuration of FIG. 5 is the decoding of the same or similar streams from the two decoders 50 and 56 within hearing distance of each other. Normally, the decoders 50 and 56 will not be in synchronization and will have some delay mismatch in the audio with respect to each other. This lack of synchronization may be particularly problematic if TV#2 58 is a portable unit. In such a case, MPEG encoder 56 may wirelessly transmit an audio and video stream to MPEG decoder 56, which in turn decodes the stream and provides corresponding audio and video signals to TV#2 58. This encode/decode path comprised of MPEG encoder 54 and MPEG decoder 56 has at least a 0.5 to 1.5 second delay before the stream is decoded and output by TV#2. This offset of the audio/video may be very uncomfortable to listen to since it is a very pronounced delay. The user of TV#2 58 also has the complication that the audio output of TV#1 52 is leading the video and audio of TV#2 58's output by this 0.5 to 1 second. That is, the user of TV#2 58 will hear the audio reproduced by TV#1 52 before the video display of TV#2 58 reproduces video content associated with the audio content being heard. An audio lead greater than approximately 8 milliseconds tends to be very disturbing to listen to since the audio is ahead of the video.

In regard to the delay problem described above, in the past program content reproduced by multiple analog TVs (e.g., NTSC TVs) in different rooms of a home was fairly consistent. However, with the advent of digital transmissions, encoders, decoders, and streaming video, the group delays found between TVs can be substantial. Another potential aspect of the problem involves two receivers that could be decoding similar content, but the resulting video may be a different aspect ratio, different frame rate, and a different resolution. Any of these variations in decoding parameters either individually or in combination will cause differences in the delivery and decoding of the video and audio streams with resulting delays between the reproduction of content in different locations.

To address the delay problem described above, the present invention uses a pause (i.e., time-shifting) feature. In the exemplary configuration of FIG. 5, this pause feature is provided by STB decoder 50 and delays (i.e., time-shifts) its decoding function to thereby delay the audio and video outputs of TV#1 52 by the same amount of delay found in the encode/decode path comprised of MPEG encoder 54 and MPEG decoder 56. By using the pause feature to introduce this delay, audio and video outputs of TV#1 52 and TV#2 58 can be substantially synchronized.

FIG. 6 shows another exemplary configuration that includes a pause feature according to an embodiment of the present invention. In particular, the exemplary configuration of FIG. 6 includes a DVD player 60 having dual pause features, as described above. As indicated in FIG. 6, DVD player 60 provides video signals to TV#1 62 and also provide corresponding audio output signals. DVD player 60 also provides audio and video signals to an is MPEG encoder 64 which encodes the audio and video signals received from DVD player 60 and provides an encoded signal to an MPEG decoder 66 which decodes the encoded signal and provides corresponding audio and video signals to TV#2 68. In the exemplary configuration of FIG. 6, audio delays with respect to each other and to the video may be controlled or adjusted to minimize the disturbance caused by audio delays with respect to each other and to the video by using the aforementioned pause features.

Referring now to FIG. 7, an example of how the present invention may be implemented is shown. In FIG. 7, STB decoder 70 having a pause feature decodes incoming bitstreams and provides corresponding audio and video signals to main TV#1 72, and also provides corresponding audio and video signals to an MPEG encoder 74. MPEG encoder 74 encodes the audio and video signals received from STB decoder 70 and wirelessly provides an encoded signal to an MPEG decoder 76 which decodes the encoded signal and provides corresponding audio and video signals to portable TV#2 78.

In the example of FIG. 7, person A is relatively close to main TV#1 72 where the volume is high and the amplifier is powerful. Person B is close to portable TV#2 78 where the volume is not too high, and the audio amplifier is not very powerful. Person A is not bothered by the audio of portable TV#2 78 since it is much lower in volume than audio of main TV#1 72. However, Person B hears both the relatively loud audio of main TV#1 72, and the fairly low audio of portable TV#2 78 and is bothered by the former since it leads the video on portable TV#2 78 by approximately 1 second. If the pause feature of STB decoder 70 is used to help this problem, the audio and video are delayed to main TV#1 72 since the decoding function of STB decoder 70 is delayed. This has no effect on Person A since his world is the same, with the exception of a 1 second delay which he can not tell exists. Meanwhile, Person B now has matched audio and the volume of audio from main TV#1 72 is no longer a problem since it is substantially synchronized with the audio from portable TV#2 78. The video and listening pleasure to both people has now been corrected without upsetting either person. This fixes the very annoying problem associated with portable encoder-based TVs.

FIG. 8 shows another example of how the present invention may be implemented. In FIG. 8, STB decoder 80 having a pause feature decodes incoming bitstreams and provides corresponding audio and video signals to main TV#1 82, and also provides corresponding audio and video signals to an MPEG encoder 84. MPEG encoder 84 encodes the audio and video signals received from STB decoder 80 and wirelessly provides an encoded signal to an MPEG decoder 86 which decodes the encoded signal and provides corresponding audio and video signals to portable TV#2 88. As indicated in FIG. 8, a microphone is provided to control the pause feature of STB decoder 80.

In the example of FIG. 8, the audio system of STB decoder 80 attempts to equalize the delays at the microphone to eliminate the echo effect by doing a cross-correlation of the two signals. The system will have a range limit of reasonable delays such as 0.1 to 2 seconds of adjustment that the function will check. If the audio doesn't match within this window due to either very low volume of main TV#1 82 or two different audio channels being found from two independent channels being watched, the pause feature can either remain constant in its delay or be switched back to normal zero delay. If the microphone is located in portable TV#2 88, both audio channels can be picked up and the delay actually measured with great accuracy. This would be very useful when only audio channels are being used for playing music. The delay compensation would be similar for this application, but the framing would have similar limitations in the granularity of the adjustments. Additional resources could be added to one or both of the TV processing to make adjustments very accurate. This would typically involve adding memory inside the video decoder processing where there is a frame-based reference for decoding. In this case, the adjustment could be made between 16 and 33 milliseconds. Audio adjustment could be made much finer depending on the audio standard and the amount of memory one cares to add to the to processing.

FIG. 9 shows a block diagram including further exemplary details of how the pause feature of the present invention may be implemented. The exemplary implementation of FIG. 9 comprises an input point 90 for receiving incoming bitstreams of encoded audio and/or video signals. A time-shift circuit 91 performs the pause feature by time-shifting the encoded signal to generate a time-shifted encoded signal. A first decoder 92 decodes the time-shifted encoded signal to generate a first decoded signal and provides the first decoded signal for a first system that includes TV#1 93. TV#1 93 converts the first decoded signal to a first user observable signal having audio and/or video content.

Input point 90 also provides the incoming bitstreams of encoded audio and/or video signals for a second system including a second decoder 94 for performing a decoding function, an encoder 95 for performing an encoding function, and a third decoder 96 for performing a decoding function. As indicated in FIG. 9, second decoder 94, encoder 95 and third decoder 96 are coupled in series. Third decoder 96 provides decoded signals to TV#2 97 which in turn generates a second user observable signal having audio and/or video content.

According to principles of the present invention, the time-shifting (i.e., pause feature) performed by time-shift circuit 91 is adjustable and enables the first user observable signal output by TV#1 93 to become substantially synchronized with the second user observable signal output by TV#2 97. The time-shifting performed by time-shift circuit 91 may be adjustable by a user in a manual fashion, such as via a sliding bar between two reference points. Alternatively, the time-shifting performed by time-shift circuit 91 may be adjusted automatically, such as by using a microphone in the manner described above in conjunction with FIG. 8. As will be described later herein, the time-shifting performed by time-shift circuit 91 may be adjustable in increments corresponding to one or more Group of Pictures (GOP) structures.

According to an exemplary embodiment, input point 90, time-shift circuit 91 and first decoder 92 are included in a unitary apparatus such as a STB, DVD player or other type of device, system and/or apparatus. However, according to another exemplary embodiment, second decoder 94 and/or encoder 95 may also be a part of this unitary apparatus. Also, first decoder 92 and second decoder 94 may be included on a single integrated circuit (IC). As indicated in FIG. 9, the signals output from encoder 95 are wirelessly transmitted to third decoder 96.

FIG. 10 shows further exemplary details of time-shift circuit 91 of FIG. 9. As indicated in FIG. 10, time-shift circuit 91 comprises a pause delay controller 100 having a subtractor 102, and a memory 104. Pause delay controller 100 controls the pause feature by adding or subtracting an offset from a normal delay control. Memory 104 holds streaming content and has random access for both reading and writing content. A control system (not expressly shown) for memory 104 has two counters: one for reading and the other for writing the content. As the data comes into memory 104, it is time-stamped and stored in a memory location based on the write counter. In playing data back, the memory location being read is controlled by the read counter.

When no delay is used, the read and write counters may provide the same reference in time and memory locations. This is typically not the case since the read counter always lags the write counter by a few cycles of memory to a few days in time. The amount of delay introduced by time-shift circuit 91 is managed by setting the value of the read counter back in time to equal the desired delay. For instance, if one hour is desired, the read counter would access memory 104 at the location that the write counter used for writing the content one hour back. By simply resetting the read counter, we can change the delay of the output from the time that the content was recorded.

Given that the delay can be controlled, a user feature can be provided by adding a fine tuning to this delay by offsetting the programmed time of the read counter by another number which represents a period of time. FIG. 10 shows this arrangement where the pause delay controller 100 has the capability to add or subtract an offset from the normal delay control. Hence, to delay the output content by an extra 100 milliseconds, we could increase the delay by a number that corresponds to 100 milliseconds of the storage time stamp. This accesses the read data further back in time from memory 104 which increases the delay between the time of writing and the time of reading the data.

Although not expressly shown in FIG. 10, a user interface (UI) may be provided to control the pause feature provided by time-shift circuit 91. The UI is may, for example, include a sliding bar between two reference points and employ software and/or hardware that use the slide value to offset a read address of memory 104. In this manner, the sliding bar (or other UI element) would permit a user to adjust the delay introduced by time-shift circuit 91 and also communicate to a user where the present system is set on the delay control. Also, the system may provide for a separate audio delay and a separate video delay which would be helpful to a user trying to optimize a large system of differing components. As portable systems become more commonplace, the described system may be particularly relevant due to the need for low bit rate compression for portable audio/video applications. Low bit rate processing may involve a large latency in the encoders due to the complexity to deliver the low bit rate.

In practice, it is noted that MPEG data is based on GOP structures that typically play approximately 0.5 seconds per GOP structure. This means that, from a practical standpoint, the granularity of the delay adjustment provided by time-shift circuit 91 may be limited to the size of the GOP structure stored in memory 104. Accordingly, a slight movement may change the delay 0.5 seconds, while a large movement may not change the delay at all if the content is already playing. If the content is stopped, the availability of the GOP is a more linear function of the time since it varies when the entire GOP is available for decoding. This variable starting time will provide a more linear control at the start of decoding, and then once started, the GOP structure will take control from that point. In the end, coarse adjustment is obtained by moving around between GOP structures, while finer adjustment changes when the first GOP structure is available for decoding.

As described herein, the present invention provides an apparatus and method for providing synchronization between user observable signals including audio and/or video signals. More specifically, an embodiment of the present invention described herein comprises introducing a delay by activating a pause feature of an apparatus, such as a STB. Another embodiment of the invention comprises providing an extra 1-2 seconds of time delay buffer memory. Ideally, the two systems would be matched in the decode timing even though a small lead/lag would still exist due to the is physical separation of the two TVs. Another aspect of the described invention comprises controlling the pause feature to introduce a variable delay. The delay varies responsive to detection of the actual delay that exists between content reproduction by a local or main device and content reproduction by a remote device. Detection may comprise, for example, using a microphone to detect the local and remote audio signals and processing the detected audio signals to establish an actual delay value. The pause feature may then be controlled responsive to the actual delay value to adjust the delay produced, thereby providing fine adjustment of the delay being introduced by the pause feature.

Accordingly, the invention described herein solves the described synchronization problem by utilizing a pause feature associated with an apparatus to delay the decoding of the program signal reproduced on a local or main TV by an amount on the order of 0.5 to 1.5 seconds so the two audio/video decoders in the TVs are substantially matched in their delays, or at least matched to an extent suitable for minimizing disturbing effects for a user. Another aspect of the invention described herein comprises use of a sensing device or detector, e.g., a microphone, to detect or determine the delay that exists in the two audio paths and cause the system to adjust the delay to within a predefined delay, such as a few milliseconds.

As described above, operation of the pause feature may be controlled to eliminate such delays or reduce such delays to an extent that renders the delay between the various reproductions not objectionable to a user. In accordance with an aspect of the described invention, control of the pause feature can be introduced to fine tune or adjust the delay by the consumer or by a manufacturer either manually, e.g., by use of a remote control or by buttons on the front panel of a device such as a STB, or automatically e.g., under microprocessor control. In the context of automatic control, a user or manufacturer could set a desired limit on a delay value (e.g., by entering a desired value in a menu displayed on a display device during a setup mode of operation of the system) and the system would then operate automatically under control of a microprocessor by detecting the existing delay (e.g., using a detector such as a microphone as described above) and controlling a variable delay in the decoding path, e.g., by adjusting the pause feature operation, to maintain the resulting delay within the specified limit.

As described above, an aspect of the system described herein is to create a delay in the paused content to match or substantially match the decoding time of a second decoder. The delay created may be either leading or lagging its normal mode as required to match the decoding time of the second decoder. The leading characteristic assumes that the pause content has already been recorded by at least the value of lead being requested, e.g., 2 seconds. The automatic system described above may involve communicating delay information between devices via a communication protocol such as HDMI so that the total system response can be optimized. Alternatively, or in conjunction with automatic control, manual adjustment of the delay may occur, e.g., a user could adjust the delay until the user is satisfied with the result.

The present invention may be applicable to various apparatuses, either with or without an integrated display device. While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

1. An apparatus, comprising:
an input point for receiving an encoded signal;
a circuit for time-shifting said encoded signal to generate a time-shifted encoded signal;
a first decoder for decoding said time-shifted encoded signal to generate a first decoded signal and for providing said first decoded signal for a first system, said first system converting said first decoded signal to a first user observable signal;
said input point providing said encoded signal for a second system including a second decoder, an encoder, and a third decoder coupled in series and generating a second user observable signal; and
wherein said time-shifting performed by said circuit is adjustable and enables said first user observable signal to become substantially synchronized with said second user observable signal.

2. The apparatus of claim 1, wherein said first decoder and said second decoder are included on a single integrated circuit.

3. The apparatus of claim 1, wherein said second decoder and said encoder are part of said apparatus.

4. The apparatus of claim 3, wherein signals output from said encoder are wirelessly transmitted to said third decoder.

5. The apparatus of claim 1, wherein said time-shifting performed by said circuit is adjustable by a user via a sliding bar between two reference points.

6. The apparatus of claim 1, wherein said time-shifting performed by said circuit is adjusted automatically.

7. The apparatus of claim 1, wherein said time-shifting performed by said circuit is adjustable in increments corresponding to one or more Group of Pictures (GOP) structures.

8. An apparatus, comprising:
means for receiving an encoded signal;
means for time-shifting said encoded signal to generate a time-shifted encoded signal;
first decoding means for decoding said time-shifted encoded signal to generate a first decoded signal and for providing said first decoded signal for a first system, said first system converting said first decoded signal to a first user observable signal;
said receiving means providing said encoded signal for a second system including second decoding means, encoding means, and third decoding means coupled in series and generating a second user observable signal; and
wherein said time-shifting performed by said time-shifting means is adjustable and enables said first user observable signal to become substantially synchronized with said second user observable signal.

9. The apparatus of claim 8, wherein said first decoding means and said second decoding means are included on a single integrated circuit.

10. The apparatus of claim 8, wherein said second decoding means and said encoding means are part of said apparatus.

11. The apparatus of claim 10, wherein signals output from said encoding means are wirelessly transmitted to said third decoding means.

12. The apparatus of claim 8, wherein said time-shifting performed by said time-shifting means is adjustable by a user via a sliding bar between two reference points.

13. The apparatus of claim 8, wherein said time-shifting performed by said time-shifting means is adjusted automatically.

14. The apparatus of claim 8, wherein said time-shifting performed by said time-shifting means is adjustable in increments corresponding to one or more Group of Pictures structures.

15. A method, comprising the steps of:
receiving an encoded signal;
time-shifting said encoded signal to generate a time-shifted encoded signal;
decoding said time-shifted encoded signal via a first decoder to generate a first decoded signal;
providing said first decoded signal for a first system;
converting said first decoded signal to a first user observable signal via said first system;
providing said encoded signal for a second system including a second decoder, an encoder, and a third decoder coupled in series;
generating a second user observable signal via said second system; and
wherein said time-shifting step is adjustable and enables said first user observable signal to become substantially synchronized with said second user observable signal.

16. The method of claim 15, wherein said first decoder and said second decoder are included on a single integrated circuit.

17. The method of claim 15, wherein said second decoder and said encoder are part of the same apparatus.

18. The method of claim 17, wherein signals output from said encoder are wirelessly transmitted to said third decoder.

19. The method of claim 15, wherein said time-shifting step is adjustable by a user via a sliding bar between two reference points.

20. The method of claim 15, wherein said time-shifting step is adjusted automatically.

21. The method of claim 15, wherein said time-shifting step is adjustable in increments corresponding to one or more Group of Pictures (GOP) structures.
